(19) United States
(12) Patent Application Publication
(10) Pub. No.: US 2026/0131618 A1
(43) Pub. Date: May 14, 2026

(54) VEHICLE

(71) Applicant: TOYOTA JIDOSHA KABUSHIKI KAISHA, Toyota-shi (JP)

(72) Inventor: Tomoya TAKEDA, Toyota-shi (JP)

(73) Assignee: TOYOTA JIDOSHA KABUSHIKI KAISHA, Toyota-shi (JP)

(21) Appl. No.: 19/259,560

(22) Filed: Jul. 3, 2025

(30) Foreign Application Priority Data
Nov. 14, 2024 (JP) 2024-199000

(51) Int. Cl. B60H 1/00; B60N 2/00; B60R 16/023; B62D 33/06; H05K 7/20

(52) U.S. Cl. CPC B60H 1/00271; B62D 33/06; B60H 2001/003; B60N 2/00; B60R 16/0231; H05K 7/20863

(57) ABSTRACT

The vehicle includes a back panel, a rear seat, and a heat dissipation fan that is disposed in a space between the back panel and the rear seat and discharges air in the space to the outside of the space, in which an air guide structure that guides air outside the space into the space is configured by the back panel and the rear seat.

### CROSS-REFERENCE TO RELATED APPLICATION

This application claims priority to Japanese Patent Application No. 2024-199000 filed on Nov. 14, 2024. The disclosure of the above-identified application, including the specification, drawings, and claims, is incorporated by reference herein in its entirety.

### BACKGROUND

### 1. Technical Field

The present disclosure relates to a vehicle.

### 2. Description of Related Art

Japanese Unexamined Patent Application Publication No. 2021-035790 (JP 2021-035790 A) discloses a vehicle including a vehicle control device that includes an electronic control unit (ECU). In addition, in a technique disclosed in JP 2021-035790 A, a cooling fan guides air into a battery box through a guidance duct to cool a sub-ECU, and the air that flows in the battery box is exhausted into a vehicle cabin through an exhaust duct.

### SUMMARY

As in the technique disclosed in JP 2021-035790 A, a technique capable of cooling the ECU without adding components, such as a box and a duct, is desired.

In consideration of the above-mentioned points, an object of the present disclosure is to provide a vehicle that can cool an ECU while addition of components is reduced.

(1) An aspect of the present disclosure is a vehicle including
a back panel,
a rear seat,
an ECU disposed in a space between the back panel and the rear seat, and
a heat dissipation fan configured to discharge air in the space to the outside of the space, in which the back panel and the rear seat constitute an air guide structure that guides air outside the space into the space.

(2) In the vehicle of (1),
the vehicle may be a pickup truck including a cargo bed,
the back panel may be disposed between the cargo bed and the rear seat and include a through hole,
the through hole may be disposed at a substantially central position of the back panel in a left-right direction,
the heat dissipation fan may be disposed at a position of the through hole,
the air outside the space, by the heat dissipation fan, may be guided into the space through a gap between a right side portion of the rear seat and the back panel, guided into the space through a gap between a left side portion of the rear seat and the back panel, and discharged to the outside of a cabin through the through hole after cooling the ECU, and
a gap between an upper portion of the rear seat and the back panel and a gap between a lower portion of the rear seat and a floor may be sealed.

(3) In the vehicle of (1),
the vehicle may be a pickup truck including a cargo bed,
the back panel may be disposed between the cargo bed and the rear seat and include a through hole,
the ECU may include a right ECU disposed at a position on a right side of a substantially central position of the back panel in a left-right direction, and a left ECU disposed at a position on a left side of the substantially central position of the back panel in the left-right direction,
the through hole may include a right through hole disposed at the position on the right side of the substantially central position of the back panel in the left-right direction, and a left through hole disposed at the position on the left side of the substantially central position of the back panel in the left-right direction,
the heat dissipation fan may include a right heat dissipation fan disposed at a position of the right through hole, and a left heat dissipation fan disposed at a position of the left through hole,
the air outside the space, by the right heat dissipation fan, may be guided into the space through a gap between a right side portion of the rear seat and the back panel and discharged to the outside of a cabin through the right through hole after cooling the right ECU, and the air outside the space, by the left heat dissipation fan, may be guided into the space through a gap between a left side portion of the rear seat and the back panel and discharged to an outside of the cabin through the left through hole after cooling the left ECU, and
a gap between an upper portion of the rear seat and the back panel and a gap between a lower portion of the rear seat and a floor may be sealed.

(4) In the vehicle of (1),
the vehicle may be a pickup truck including a cargo bed,
the back panel may be disposed between the cargo bed and the rear seat, the ECU may include a right ECU disposed at a position on a right side of a substantially central position of the back panel in a left-right direction, and a left ECU disposed at a position on a left side of the substantially central position of the back panel in the left-right direction,
the heat dissipation fan may be disposed at the substantially central position of the back panel in the left-right direction, and
the air outside the space, by the heat dissipation fan, may be guided into the space through a gap between a right side portion of the rear seat and the back panel and discharged to the outside of a cabin through a gap between an upper portion of the rear seat and the substantially central position of the back panel in the left-right direction after cooling the right ECU, and guided into the space through a gap between a left side portion of the rear seat and the back panel and discharged to the outside of the space through the gap between the upper portion of the rear seat and the substantially central position of the back panel in the left-right direction after cooling the left ECU.

(5) In the vehicle of (1),
the vehicle may be a pickup truck including a cargo bed,
the back panel may be disposed between the cargo bed and the rear seat,
the air outside the space, by the heat dissipation fan, may be guided into the space through one of a gap between a right side portion of the rear seat and the back panel and a gap between a left side portion of the rear seat and the back panel, and discharged to the outside of the space through the heat dissipation fan disposed in the other of the gap between the right side portion of the rear seat and the back panel and the gap between the left side portion of the rear seat and the back panel after cooling the ECU, and
a gap between an upper portion of the rear seat and the back panel and a gap between a lower portion of the rear seat and a floor may be sealed.

According to the present disclosure, it is possible to cool the ECU while the addition of the components is reduced.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1A is a diagram showing an example of a vehicle 100 of a first embodiment;

FIG. 1B is a diagram showing an example of the vehicle 100 of the first embodiment;

FIG. 2A is a diagram schematically showing a cross section of the vehicle 100 of the first embodiment;

FIG. 2B is a diagram schematically showing the cross section of the vehicle 100 of the first embodiment;

FIG. 3 is a diagram showing an example of a schematic horizontal cross section of a rear seat 12, a back panel 13, and the like of the vehicle 100 of a second embodiment;

FIG. 4 is a perspective view of the rear seat 12 and the like of the vehicle 100 of a third embodiment;

FIG. 5A is a diagram schematically showing a cross section of the vehicle 100 of the third embodiment;

FIG. 5B is a diagram schematically showing the cross section of the vehicle 100 of the third embodiment;

FIG. 6 is a perspective view of the rear seat 12 and the like of the vehicle 100 of a fourth embodiment;

FIG. 7A is a diagram schematically showing a cross section of the vehicle 100 of a fourth embodiment; and

FIG. 7B is a diagram schematically showing the cross section of the vehicle 100 of the fourth embodiment.

### DETAILED DESCRIPTION OF EMBODIMENTS

Hereinafter, embodiments of a vehicle of the present disclosure will be described with reference to the drawings.

### First Embodiment

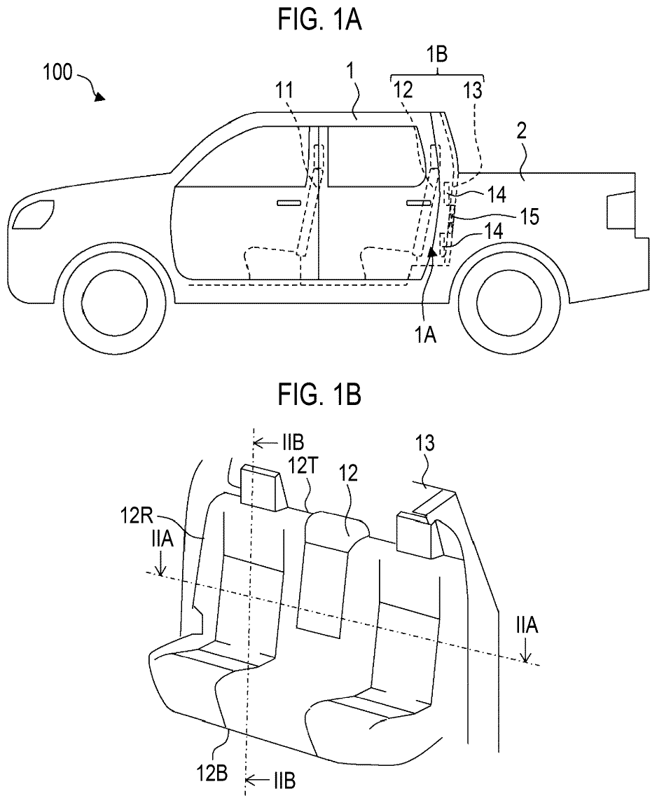

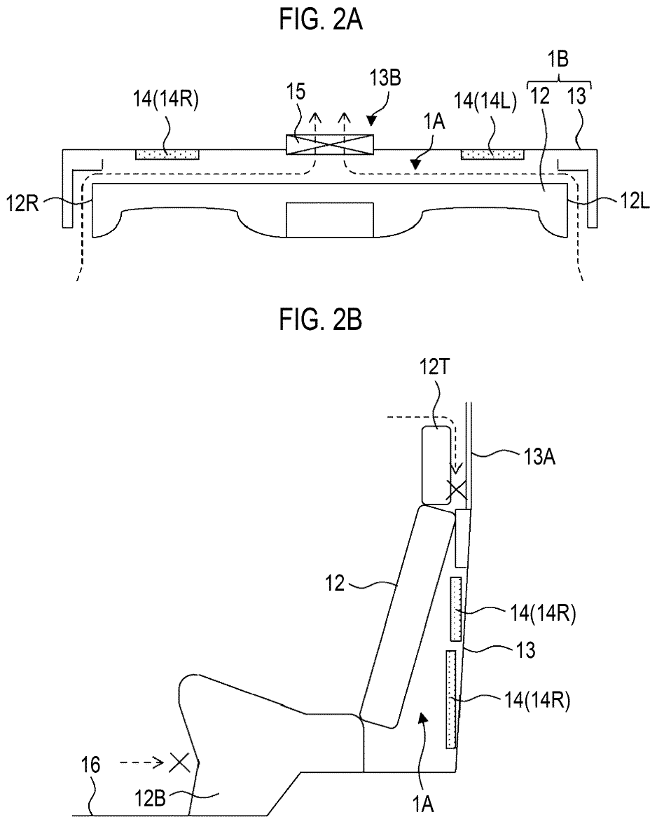

FIGS. 1A and 1B are diagrams showing an example of a vehicle 100 of a first embodiment. Specifically, FIG. 1A shows the appearance of the vehicle 100 by a solid line, and shows the inside of the vehicle 100 by a broken line. FIG. 1B is a perspective view of a rear seat 12 and the like of the vehicle 100. FIGS. 2A and 2B are diagrams schematically showing cross sections of the vehicle 100 of the first embodiment. Specifically, FIG. 2A shows a schematic horizontal cross section taken along an IIA-IIA line of FIG. 1B, and FIG. 2B shows a schematic vertical cross section taken along an IIB-IIB line of FIG. 1B.

In the examples shown in FIGS. 1A, 1B, 2A, and 2B, the vehicle 100 of the first embodiment is a pickup truck including a cabin 1 and a cargo bed 2. In addition, the vehicle 100 includes a front seat 11, the rear seat 12, a back panel 13, an ECU 14 (for example, an ECU for autonomous driving), and a heat dissipation fan 15.

As shown in FIG. 1A, the back panel 13 is disposed between the cargo bed 2 and the rear seat 12. In addition, the back panel 13 includes a rear window 13A (see FIG. 2B) and a through hole 13B (see FIG. 2A). As shown in FIG. 2A, the through hole 13B is disposed at a substantially central position of the back panel 13 in the left-right direction (left-right direction in FIG. 2A).

As shown in FIGS. 1A, 2A, and 2B, the ECU 14 is disposed in a space 1A between the back panel 13 and the rear seat 12. As shown in FIG. 2A, the ECU 14 includes a right ECU 14R and a left ECU 14L. The right ECU 14R is disposed at a position to the right side (to the left side in FIG. 2A) of the substantially central position of the back panel 13 in the left-right direction (left-right direction in FIG. 2A). The left ECU 14L is disposed at a position to the left side (right side in FIG. 2A) of the substantially central position of the back panel 13 in the left-right direction.

The heat dissipation fan 15 is disposed at a position of the through hole 13B of the back panel 13, and discharges the air in the space 1A to the outside of the space 1A. In detail, the heat dissipation fan 15 discharges the air in the space 1A to the outside of the cabin 1 through the through hole 13B of the back panel 13. As the heat dissipation fan 15, for example, an axial flow fan is used.

As shown by a broken line arrow for air flow in FIG. 2A, an air guide structure 1B that guides the air outside the space 1A into the space 1A is configured by the back panel 13 and the rear seat 12.

Specifically, as indicated by the broken line arrow in FIG. 2A, the air outside the space 1A is guided into the space 1A through a gap between a right side portion 12R of the rear seat 12 and the back panel 13 by the heat dissipation fan 15. The air guided into the space 1A is discharged to the outside of the cabin 1 through the through hole 13B (passing through the heat dissipation fan 15) after cooling the ECU 14 (right ECU 14R). In addition, the air outside the space 1A is guided into the space 1A through a gap between a left side portion 12L of the rear seat 12 and the back panel 13 by the heat dissipation fan 15. The air guided into the space 1A is discharged to the outside of the cabin 1 through the through hole 13B (passing through the heat dissipation fan 15) after cooling the ECU 14 (left ECU 14L). As a result, an entirety of the space 1A is ventilated.

As shown in FIG. 2B, the gap between an upper portion 12T of the rear seat 12 and the back panel 13 is sealed. Therefore, the air outside the space 1A is not guided into the space 1A through the gap between the upper portion 12T of the rear seat 12 and the back panel 13. In addition, the gap between a lower portion 12B of the rear seat 12 and a floor 16 is also sealed. Therefore, the air outside the space 1A is not guided into the space 1A through the gap between the lower portion 12B of the rear seat 12 and the floor 16.

As described above, in the examples shown in FIGS. 1A, 1B, 2A, and 2B, the air that cools the ECU 14 is rectified by using the back panel 13 and the rear seat 12. As a result, the ECU 14 can be cooled while the addition of components, such as a duct, is reduced. That is, it is possible to suppress a risk that the heat generated by the ECU 14 is trapped.

### Second Embodiment

The vehicle 100 of the second embodiment is configured in the same manner as the vehicle 100 of the first embodiment described above, except for the points described below.

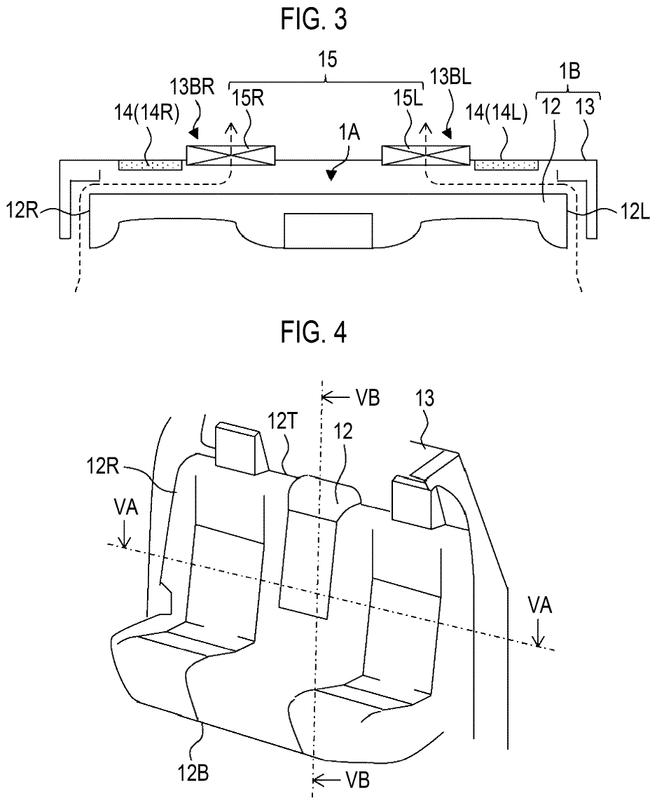

FIG. 3 is a diagram showing an example of a schematic horizontal cross section of the rear seat 12, the back panel 13, and the like of the vehicle 100 of the second embodiment. In the example shown in FIG. 3, the back panel 13 includes a right through hole 13BR and a left through hole 13BL. The right through hole 13BR is disposed at a position to the right side (left side in FIG. 3) of the substantially central position of the back panel 13 in the left-right direction (left-right direction in FIG. 3). The left through hole 13BL is disposed at a position to the left side (right side in FIG. 3) of the substantially central position of the back panel 13 in the left-right direction. That is, the right through hole 13BR and the left through hole 13BL are included in the through hole 13B of the back panel 13.

The heat dissipation fan 15 includes a right heat dissipation fan 15R and a left heat dissipation fan 15L. The right heat dissipation fan 15R is disposed at a position of the right through hole 13BR of the back panel 13, and the left heat dissipation fan 15L is disposed at a position of the left through hole 13BL of the back panel 13. As the right heat dissipation fan 15R and the left heat dissipation fan 15L, for example, an axial flow fan is used.

As shown by a broken line arrow for air flow in FIG. 3, the air guide structure 1B that guides the air outside the space 1A into the space 1A is configured by the back panel 13 and the rear seat 12.

Specifically, as shown by the broken line arrow in FIG. 3, the air outside the space 1A is guided into the space 1A through a gap between the right side portion 12R of the rear seat 12 and the back panel 13 by the right heat dissipation fan 15R. The air guided into the space 1A cools the ECU 14 (right ECU 14R) and is then discharged to the outside of the cabin 1 through the right through hole 13BR (passes through the right heat dissipation fan 15R). In addition, the air outside the space 1A is guided into the space 1A through a gap between the left side portion 12L of the rear seat 12 and the back panel 13 by the left heat dissipation fan 15L. The air guided into the space 1A is discharged to the outside of the cabin 1 through the left through hole 13BL (through the left heat dissipation fan 15L) after cooling the ECU 14 (the left ECU 14L).

In the example shown in FIG. 3, two heat dissipation fans 15 (right heat dissipation fan 15R and left heat dissipation fan 15L) are provided, but in another example, a number of heat dissipation fans 15 other than two (provided that the number is plural) may be provided.

### Third Embodiment

The vehicle 100 of the third embodiment is configured in the same manner as the vehicle 100 of the first embodiment described above, except for the points described below.

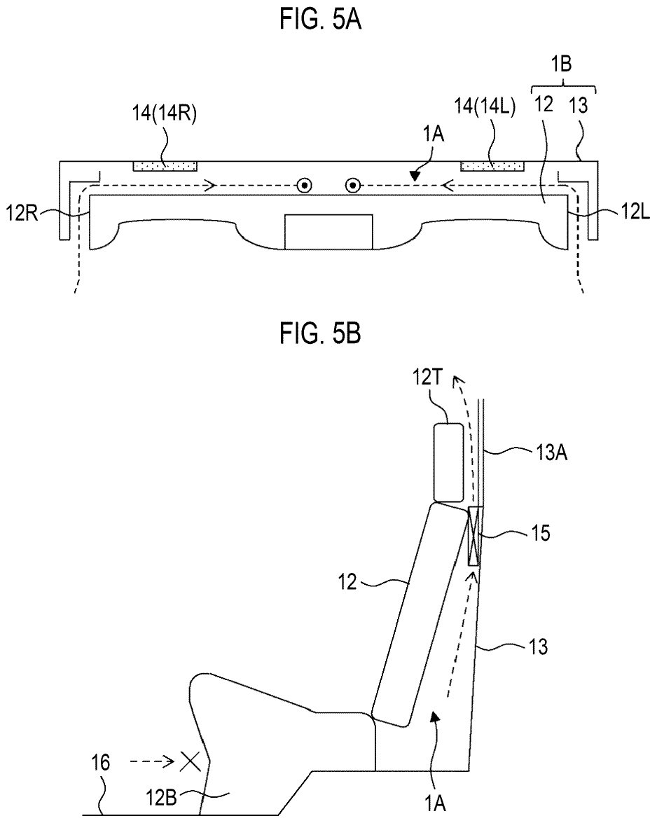

FIG. 4 is a perspective view of the rear seat 12 and the like of the vehicle 100 of the third embodiment. FIGS. 5A and 5B are diagrams schematically showing cross sections of the vehicle 100 of the third embodiment. Specifically, FIG. 5A shows a schematic horizontal cross section along the VA-VA line of FIG. 4, and FIG. 5B shows a schematic vertical cross section along the VB-VB line of FIG. 4.

In the examples shown in FIGS. 4, 5A, and 5B, the ECU 14 is disposed in the space 1A between the back panel 13 and the rear seat 12. As shown in FIG. 5A, the ECU 14 includes the right ECU 14R and the left ECU 14L. The right ECU 14R is disposed at a position to the right side (left side in FIG. 5A) of the substantially central position of the back panel 13 in the left-right direction (left-right direction in FIG. 5A). The left ECU 14L is disposed at a position to the left side (right side in FIG. 5A) of the substantially central position of the back panel 13 in the left-right direction.

The heat dissipation fan 15 is disposed at a substantially central position of the back panel 13 in the left-right direction (left-right direction in FIG. 5A) and in a gap between the upper portion 12T of the rear seat 12 and the back panel 13, and discharges the air in the space 1A to the outside of the space 1A. Specifically, the heat dissipation fan 15 discharges the air in the space 1A to the outside of the space 1A (passes through the heat dissipation fan 15) through the gap between the upper portion 12T of the rear seat 12 and the back panel 13. As the heat dissipation fan 15, for example, a cross flow fan that can be disposed in a gap between the upper portion 12T of the rear seat 12 and the back panel 13 is used. In another example, a plurality of axial flow fans with a small diameter that can be disposed in a gap between the upper portion 12T of the rear seat 12 and the back panel 13 may be used as the heat dissipation fan 15.

In the examples shown in FIGS. 4, 5A, and 5B, as shown by a broken line arrow for air flow in FIG. 5A, the air guide structure 1B that guides the air outside the space 1A into the space 1A is configured by the back panel 13 and the rear seat 12. Specifically, as shown by a broken line arrow in FIG. 5A, the air outside the space 1A is guided into the space 1A through a gap between the right side portion 12R of the rear seat 12 and the back panel 13 by the heat dissipation fan 15. The air guided into the space 1A is discharged to the outside of the space 1A through a gap between the upper portion 12T of the rear seat 12 and a substantially central position of the back panel 13 in the left-right direction (left-right direction in FIG. 5A) as indicated by the broken line arrow in FIG. 5B after cooling the ECU 14 (right ECU 14R). In this case, the air discharged to the outside of the space 1A is discharged through the heat dissipation fan 15. In addition, as indicated by a broken line arrow in FIG. 5A, the air outside the space 1A is guided into the space 1A through the gap between the left side portion 12L of the rear seat 12 and the back panel 13 by the heat dissipation fan 15. The air guided into the space 1A is discharged to the outside of the space 1A through a gap between the upper portion 12T of the rear seat 12 and a substantially central position of the back panel 13 in the left-right direction (left-right direction in FIG. 5A) as indicated by a broken line arrow in FIG. 5B after cooling the ECU 14 (left ECU 14L). In this case, the air discharged to the outside of the space 1A is discharged through the heat dissipation fan 15. As a result, an entirety of the space 1A is ventilated.

As shown in FIG. 5B, the gap between the lower portion 12B of the rear seat 12 and the floor 16 is sealed. Therefore, the air outside the space 1A is not guided into the space 1A through the gap between the lower portion 12B of the rear seat 12 and the floor 16.

### Fourth Embodiment

The vehicle 100 of the fourth embodiment is configured in the same manner as the vehicle 100 of the first embodiment described above, except for the points described below.

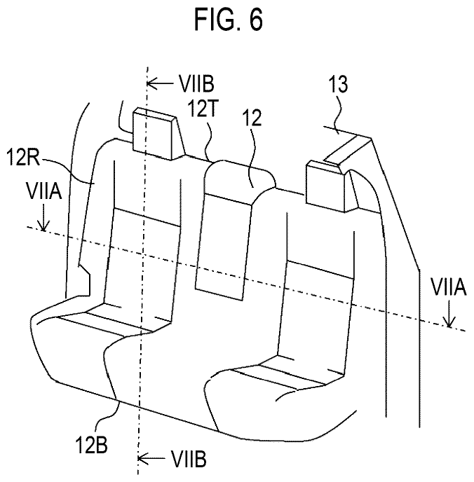

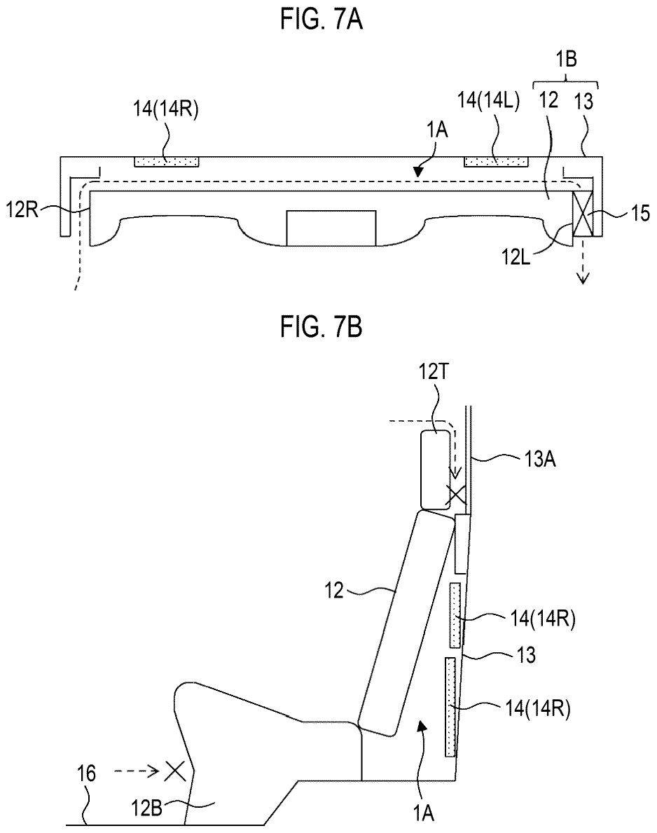

FIG. 6 is a perspective view of the rear seat 12 and the like of the vehicle 100 of the fourth embodiment. FIGS. 7A and 7B are diagrams schematically showing cross sections of the vehicle 100 of the fourth embodiment. Specifically, FIG. 7A shows a schematic horizontal cross section along a VIIA-VIIA line of FIG. 6, and FIG. 7B shows a schematic vertical cross section along a VIIB-VIIB line of FIG. 6.

In the examples shown in FIGS. 6, 7A, and 7B, the ECU 14 is disposed in the space 1A between the back panel 13 and the rear seat 12. As shown in FIG. 7A, the ECU 14 includes the right ECU 14R and the left ECU 14L. The right ECU 14R is disposed at a position to the right side (to the left side in FIG. 7A) of the substantially central position of the back panel 13 in the left-right direction (left-right direction in FIG. 7A). The left ECU 14L is disposed at a position to the left side (right side in FIG. 7A) of the substantially central position of the back panel 13 in the left-right direction.

The heat dissipation fan 15 is disposed in a gap between the left side portion 12L of the rear seat 12 and the back panel 13, and discharges the air in the space 1A to the outside of the space 1A. Specifically, the heat dissipation fan 15 discharges the air in the space 1A to the outside of the space 1A through the gap between the left side portion 12L of the rear seat 12 and the back panel 13. As the heat dissipation fan 15, for example, a cross flow fan that can be disposed at a position of a gap between the left side portion 12L of the rear seat 12 and the back panel 13 is used. In another example, a plurality of axial flow fans with a small diameter may be used as the heat dissipation fan 15.

In the examples shown in FIGS. 6, 7A, and 7B, as indicated by a broken line arrow for air flow in FIG. 7A, the air guide structure 1B that guides the air outside the space 1A into the space 1A is configured by the back panel 13 and the rear seat 12. Specifically, as indicated by a broken line arrow in FIG. 7A, the air outside the space 1A is guided into the space 1A through a gap between the right side portion 12R of the rear seat 12 and the back panel 13 by the heat dissipation fan 15. The air guided into the space 1A cools the ECU 14 (right ECU 14R and left ECU 14L), and then is discharged to the outside of the space 1A through the heat dissipation fan 15. The heat dissipation fan 15 is disposed in a gap between the left side portion 12L of the rear seat 12 and the back panel 13. As a result, an entirety of the space 1A is ventilated.

As shown in FIG. 7B, the gap between the lower portion 12B of the rear seat 12 and the floor 16 is sealed. Therefore, the air outside the space 1A is not guided into the space 1A through the gap between the lower portion 12B of the rear seat 12 and the floor 16.

In another example of the vehicle 100 of the fourth embodiment, the heat dissipation fan 15 may be disposed in a gap between the right side portion 12R of the rear seat 12 and the back panel 13 to discharge the air in the space 1A to the outside of the space 1A. In this example, the heat dissipation fan 15 discharges the air in the space 1A to the outside of the space 1A through the gap between the right side portion 12R of the rear seat 12 and the back panel 13.

Specifically, in this example, the air outside the space 1A is guided into the space 1A through the gap between the left side portion 12L of the rear seat 12 and the back panel 13 by the heat dissipation fan 15. The air guided into the space 1A cools the ECU 14 (the left ECU 14L and the right ECU 14R), and then is discharged to the outside of the space 1A through the heat dissipation fan 15 disposed in a gap between the right side portion 12R of the rear seat 12 and the back panel 13. As a result, an entirety of the space 1A is ventilated.

As described above, the embodiment of the vehicle of the present disclosure has been described with reference to the drawings. However, the vehicle of the present disclosure is not limited to the above-described embodiment, and can be appropriately modified within the scope of the spirit of the present disclosure. The configuration of each of the examples of the above-described embodiments may be appropriately combined.

What is claimed is:

1. A vehicle comprising:
a back panel;
a rear seat;
an ECU disposed in a space between the back panel and the rear seat; and
a heat dissipation fan configured to discharge air in the space to an outside of the space,
wherein the back panel and the rear seat constitute an air guide structure that guides air outside the space into the space.

2. The vehicle according to claim 1, wherein:
the vehicle is a pickup truck including a cargo bed;
the back panel is disposed between the cargo bed and the rear seat and includes a through hole;
the through hole is disposed at a substantially central position of the back panel in a left-right direction;
the heat dissipation fan is disposed at a position of the through hole;
the air outside the space, by the heat dissipation fan, is guided into the space through a gap between a right side portion of the rear seat and the back panel, is guided into the space through a gap between a left side portion of the rear seat and the back panel, and is discharged to an outside of a cabin through the through hole after cooling the ECU; and
a gap between an upper portion of the rear seat and the back panel and a gap between a lower portion of the rear seat and a floor are sealed.

3. The vehicle according to claim 1, wherein:
the vehicle is a pickup truck including a cargo bed;
the back panel is disposed between the cargo bed and the rear seat and includes a through hole;
the ECU includes a right ECU disposed at a position on a right side of a substantially central position of the back panel in a left-right direction, and a left ECU disposed at a position on a left side of the substantially central position of the back panel in the left-right direction;
the through hole includes a right through hole disposed at the position on the right side of the substantially central position of the back panel in the left-right direction, and a left through hole disposed at the position on the left side of the substantially central position of the back panel in the left-right direction;
the heat dissipation fan includes a right heat dissipation fan disposed at a position of the right through hole, and a left heat dissipation fan disposed at a position of the left through hole;
the air outside the space, by the right heat dissipation fan, is guided into the space through a gap between a right side portion of the rear seat and the back panel and is discharged to an outside of a cabin through the right through hole after cooling the right ECU, and the air outside the space, by the left heat dissipation fan, is guided into the space through a gap between a left side portion of the rear seat and the back panel and is discharged to an outside of the cabin through the left through hole after cooling the left ECU; and
a gap between an upper portion of the rear seat and the back panel and a gap between a lower portion of the rear seat and a floor are sealed.

4. The vehicle according to claim 1, wherein:
the vehicle is a pickup truck including a cargo bed;
the back panel is disposed between the cargo bed and the rear seat;
the ECU includes a right ECU disposed at a position on a right side of a substantially central position of the back panel in a left-right direction, and a left ECU disposed at a position on a left side of the substantially central position of the back panel in the left-right direction;
the heat dissipation fan is disposed at the substantially central position of the back panel in the left-right direction; and
the air outside the space, by the heat dissipation fan, is guided into the space through a gap between a right side portion of the rear seat and the back panel and is discharged to an outside of a cabin through a gap between an upper portion of the rear seat and the substantially central position of the back panel in the left-right direction after cooling the right ECU, and is guided into the space through a gap between a left side portion of the rear seat and the back panel and is discharged to the outside of the space through the gap between the upper portion of the rear seat and the substantially central position of the back panel in the left-right direction after cooling the left ECU.

5. The vehicle according to claim 1, wherein:
the vehicle is a pickup truck including a cargo bed;
the back panel is disposed between the cargo bed and the rear seat;
the air outside the space, by the heat dissipation fan, is guided into the space through one of a gap between a right side portion of the rear seat and the back panel and a gap between a left side portion of the rear seat and the back panel, and is discharged to the outside of the space through the heat dissipation fan disposed in the other of the gap between the right side portion of the rear seat and the back panel and the gap between the left side portion of the rear seat and the back panel after cooling the ECU; and
a gap between an upper portion of the rear seat and the back panel and a gap between a lower portion of the rear seat and a floor are sealed.
